(19) United States
(12) Patent Application Publication
(10) Pub. No.: US 2009/0114273 A1
(43) Pub. Date: May 7, 2009

(54) NANOMATERIAL SCAFFOLDS FOR ELECTRON TRANSPORT

(75) Inventor: Prashant Kamat, Granger, IN (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(73) Assignee: University of Notre Dame du Lac, Notre Dame, IN (US)

(21) Appl. No.: 12/136,879

(22) Filed: Jun. 11, 2008

Related U.S. Application Data
(60) Provisional application No. 60/934,403, filed on Jun. 13, 2007.

(51) Int. Cl. H01L 31/00; H01B 1/04

(52) U.S. Cl. 136/252; 252/501.1; 977/748; 977/831

(57) ABSTRACT

Embodiments of the present invention provide nanomaterial scaffolds for transporting electrons. There is provided a single wall carbon nanotube (SWCNT) architecture employed as a conducting scaffold in semiconductor based photoelectrochemical cells. SWCNT architecture provides a nanotube network to disperse nanoparticles and/or quantum dots, whether ordered or randomized. As a result, an increase in incident photon conversion to charge carrier conversion efficiency (IPCE) represents a beneficial role of SWCNT architecture as a conducting scaffold to facilitate charge collection and charge transport in nanostructured semiconductor films. Embodiments may be used for solar cells based on semiconductor quantum dots and nanostructures, solar hydrogen production, microcapacitors and storage batteries, solar-fuel cell hybrids, etc.

### CROSS REFERENCE TO RELATED APPLICATIONS

The present application claims priority to U.S. Provisional Patent Application No. 60/934,403, filed Jun. 13, 2007, entitled “Single Wall Carbon Nanotube Scaffolds for Boosting the Efficiency of Solar Cells,” the entire disclosure of which is hereby incorporated by reference in its entirety.

### GOVERNMENT INTERESTS

This invention was made with Government support under Grant/Contract No. DE-FC02-04ER15533 awarded by the US Department of Energy. The Government may have certain rights in the invention.

### TECHNICAL FIELD

Embodiments of the present invention relate to the fields of nanotechnology and energy, and, more specifically, to nanomaterial scaffolds for transporting electrons, such as for use in photoelectrochemical solar cells.

### BACKGROUND

The photocatalytic activity of semiconductor films has been widely explored in designing solar cells, solar hydrogen production and environmental remediation. Of particular interest is the dye-sensitized solar cell (DSSC) which uses mesoscopic TiO₂ films modified with sensitizing dyes. Despite the initial success of achieving 10% solar conversion efficiency, the effort to further improve their performance has not resulted in breakthroughs. A major hurdle in attaining higher photoconversion efficiency in such nanostructured electrodes is the transport of electrons across the particle network. The photogenerated electrons in mesoscopic films for example have to travel through the network of semiconductor particles and encounter many grain boundaries during the transit. Such a random transit path for the photogenerated electrons increases the probability of their recombination with oxidized sensitizer. The use of a redox couple such as I₃⁻/I⁻ facilitates the electron transport to some extent by rapid regeneration of the oxidized sensitizer. However, the conversion efficiency is still not entirely favorable.

### BRIEF DESCRIPTION OF THE DRAWINGS

Embodiments of the present invention will be readily understood by the following detailed description in conjunction with the accompanying drawings. Embodiments of the invention are illustrated by way of example and not by way of limitation in the figures of the accompanying drawings.

FIGS. 1A and 1B illustrate electron transport across a semiconductor particle based film (FIG. 1A; prior art), and in the presence of a nanotube support architecture (FIG. 1B) in accordance with various embodiments of the present invention;

FIG. 2, rows A-D, illustrate scanning electron micrographs of carbon fiber electrodes (CFE) at different stages of modification: (A) before surface modification, (B) after modification with TiO₂ particles, (C) after electrophoretic deposition of SWCNT, and (D) after deposition of TiO₂ particles onto SWCNT film;

FIG. 3A illustrates photocurrent response versus time profiles of CFE/SWCNT/TiO₂ (a) and CFE/TiO₂ (b) electrodes at 0 V versus SCE; light intensity was 50 mW/cm² (λ>300 nm). FIG. 3B illustrates photocurrent action spectra of CFE/SWCNT/TiO₂ (a, b) and CFE/TiO₂ (c, d) electrodes at no applied bias (b, d) and at 0 V versus SCE (a, c); IPCE(%)=(1240×i_{sc})(λ×I_{inc})×100 where i_{sc} is short circuit current and I_{inc} is the power of the incident light; electrolyte was N₂-sat 1 M KOH solution;

FIG. 4 illustrates photocurrent response as a function of the amount of TiO₂ deposited on CFE or CFE/SWCNT electrodes; SWCNT concentration was maintained constant at 0.2 mg/cm² while TiO₂ loading was varied;

FIG. 5 illustrates I-V characteristics for OTE/TiO₂ (c, d) and OTE/SWCNT/TiO₂ (a, b) obtained with (b, d) and without (a, c) light illumination from the backside of the OTE; TiO₂ and SWCNT loadings were 2 and 0.01 mg/cm² respectively;

FIGS. 6A and 6B illustrate photocurrent and photovoltage response, respectively, of (a) OTE/TiO₂/Ru(II) and (b) OTE/SWCNT/TiO₂/Ru(II) electrodes; light intensity was 50 mW/cm² (λ>400 nm); electrolyte was 0.5 M LiI and 0.05 M I₂ in acetonitrile;

FIG. 7 is an energy diagram illustrating the charge injection from excited sensitizer (S*) into TiO₂ and transport of photoinjected electrons to the electrode surface without (a) and with (b) SWCNT network; the Fermi level of TiO₂ (E_{f}′) shifts to more positive potentials (E_{f}′) as it equilibrates with SWCNT;

FIG. 8 illustrates photocurrent action spectra of (a) OTE/TiO₂/Ru(II), and (b) OTE/SWCNT/TiO₂/Ru(II) electrodes; IPCE(%)=(1240×i_{sc})/(λ×I_{inc})×100 where i_{sc} is short circuit current and I_{inc} is the power of the incident light; electrolyte was 0.5 M LiI and 0.05 M I₂ in acetonitrile;

FIG. 9 illustrates power characteristics of a photoelectrochemical cell employing (a) OTE/TiO₂/Ru(II), and (b) OTE/SWCNT/TiO₂/Ru(II) electrodes; electrolyte was 0.5 M LiI and 0.05 M I₂ in acetonitrile;

FIGS. 10A and 10B illustrate random versus directed electron transport through support architectures; FIG. 10A illustrates TiO₂ particle architecture, and FIG. 10B illustrates TiO₂ nanotube films modified with CdSe quantum dots;

FIG. 11A illustrates photocurrent response of OTE/TiO₂(NP)/CdSe and FIG. 11B illustrates photocurrent response of Ti/TiO₂(NT)/CdSe electrodes; individual traces correspond to (a) 2.3, (b) 2.6, (c) 3.0, and (d) 3.7 nm diameter CdSe quantum dots anchored on nanostructured TiO₂ films (excitation >420 nm, 100 mW/cm², electrolyte: 0.1 M Na₂S solution);

FIGS. 12A and 12B illustrate photocurrent action spectra recorded in terms of incident photon to charge carrier generation efficiency (IPCE) of OTE/TiO₂(NP)/CdSe and Ti/TiO₂(NT)/CdSe electrodes, respectively; the individual IPCE responses correspond to (a) 2.3, (b) 2.6, (c) 3.0, and (d) 3.7 nm diameter CdSe quantum dots anchored on nanostructured TiO₂ films;

FIG. 13 illustrates emission spectra of (a, b) 2.6 nm and (c, d) 3.7 nm diameter CdSe quantum dot films deposited on glass (a, c) and TiO₂ films, (b, d) excitation was at 480 nm; the spectra (b) and (d) carry a multiplication factor of 3; all spectra were recorded using front face geometry;

FIGS. 14A and 14B illustrate emission decay of 2.6 nm (emission at 540 nm) and 3.7 nm diameter (emission at 580 nm) CdSe quantum dots deposited on a glass slide, TiO₂ nanoparticulate film, and TiO₂ nanotube array; excitation wavelength was 457 nm; solid lines represent kinetic fit using triexponential decay analysis; prompt measurement of instrument response used to mathematically deconvolute best-fit curve is also shown;

FIG. 15 is a schematic diagram illustrating the energy levels of different size CdSe quantum dots and TiO₂; the injection of electrons from CdSe quantum dots into TiO₂ is influenced by the energy difference between the two conduction bands (band positions are for reference only and not drawn to scale); and

FIG. 16 is a schematic illustration of a rainbow solar cell assembled with different size CdSe quantum dots on a TiO₂ nanotube array.

### DETAILED DESCRIPTION OF EMBODIMENTS OF THE INVENTION

In the following detailed description, reference is made to the accompanying drawings which form a part hereof, and in which are shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The description may use perspective-based descriptions such as up/down, back/front, and top/bottom. Such descriptions are merely used to facilitate the discussion and are not intended to restrict the application of embodiments of the present invention.

The terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

For the purposes of the description, a phrase in the form “A/B” or in the form “A and/or B” means (A), (B), or (A and B). For the purposes of the description, a phrase in the form “at least one of A, B, and C” means (A), (B), (C), (A and B), (A and C), (B and C), or (A, B and C). For the purposes of the description, a phrase in the form “(A)B” means (B) or (AB) that is, A is an optional element.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

Embodiments of the present invention provide nanomaterial scaffolds for transporting electrons.

In an embodiment, there is provided a single wall carbon nanotube (SWCNT) architecture employed as a conducting scaffold in semiconductor based photoelectrochemical cells. In an embodiment, such a configuration may boost photoconversion efficiency. In an embodiment, such a configuration may boost photoconversion efficiency by a factor of two or more.

In an embodiment, SWCNT architecture provides a nanotube network to disperse titanium dioxide (TiO₂) particles, or other nanoparticles, such as SnO₂ or others. In an embodiment, an increase in incident photon conversion to charge carrier conversion efficiency (IPCE) represents a beneficial role of SWCNT architecture as a conducting scaffold to facilitate charge collection and charge transport in nanostructured semiconductor films. Such nanotube/nanoparticle architecture may provide a variety of benefits, including improving the efficiency of nanostructure based solar cells, e.g., dye sensitized solar cells, or in water photoelectrolysis. Embodiments may be used for solar cells based on semiconductor quantum dots and nanostructures, solar hydrogen production, microcapacitors and storage batteries, solar-fuel cell hybrids, etc.

In an embodiment, there is provided a nanostructured material, comprising a single wall carbon nanotube having a first and second end and an outer and inner surface, the first end of the single wall carbon nanotube coupled to a substrate, and a plurality of nanoparticles coupled to the single wall carbon nanotube.

In an embodiment, TiO₂ nanoparticles may be dispersed on single wall carbon nanotubes to improve photoinduced charge separation and transport of carriers to the collecting electrode surface. In accordance with an embodiment, a shift of ˜100 mV in apparent Fermi level of an SWCNT/TiO₂ system as compared to an unsupported TiO₂ system indicates the Fermi level equilibration between the two systems.

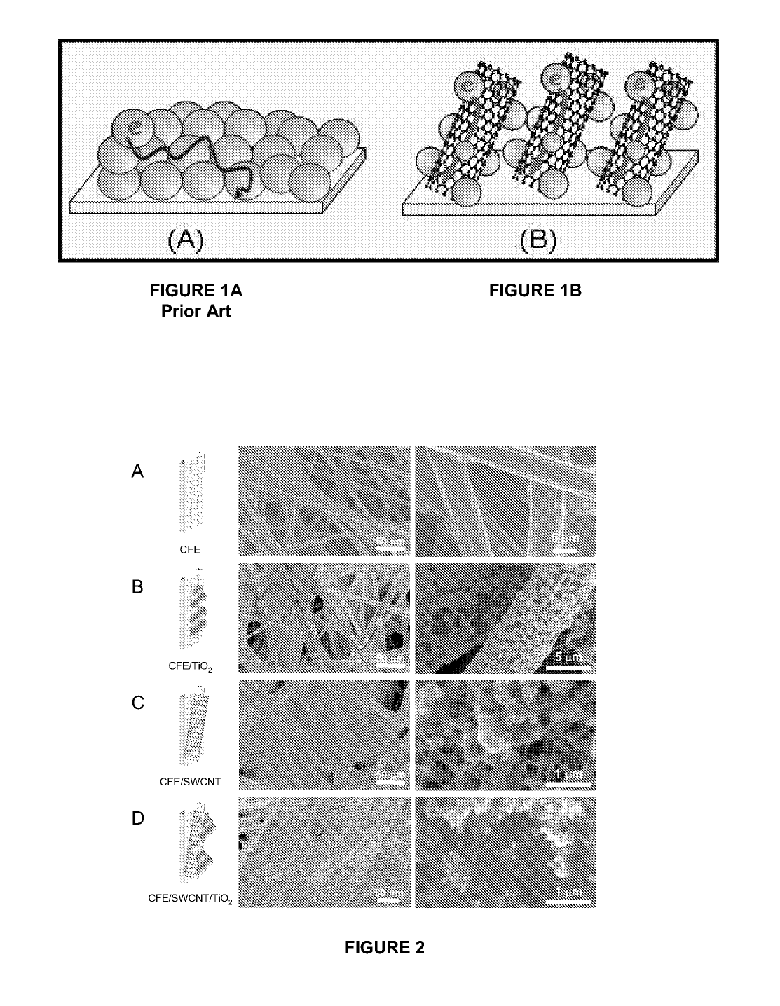

In an embodiment of the invention, one dimensional nanostructures may be used to direct the flow of photogenerated charge carriers. In an embodiment, a nanotube network may be used as a support to anchor light harvesting semiconductor particles and may facilitate the electron transport to the collecting electrode surface/substrate in a photovoltaic/solar cell. Scenarios that illustrate the electron transport in a semiconductor particle based film and an exemplary nanotube-nanoparticle composite are presented in FIGS. 1A and 1B, respectively. The particle based film and nanotube-nanoparticle composite are shown coupled to a collecting electrode surface/substrate, which may be, in an embodiment, part of a photovoltaic/solar cell. In a further embodiment, the collecting electrode surface/substrate may be further coupled to one or more other electronic components for further handling/processing of the harvested energy.

In embodiments, the term “substrate” may refer to any suitable substrate used, for example, as a collecting electrode surface/substrate, including one or more of silicon, metal, polymers, etc.

The unique electrical and electronic properties, wide electrochemical stability window, and high surface area render SWCNT beneficial as a scaffold to anchor light harvesting assemblies. In accordance with an embodiment, the electron accepting ability of semiconducting SWCNT thus offers an opportunity to facilitate electron transport and thus increase the photoconversion efficiency of nanostructure semiconductor based solar cells. In further embodiments, semiconductor particles, such as CdSe and CdTe, may be attached to carbon nanotubes directly, to other nanoparticles, and/or via functional linker molecules and may induce charge transfer processes under visible light irradiation.

SWCNT networks may be constructed using a variety of methods. In accordance with an exemplary embodiment, FIG. 2 shows low and high magnification scanning electron micrographs (SEM images) of carbon fiber paper (carbon fiber electrodes (CFE)) at different stages of modification. Preparation of the carbon fiber paper may be done using any of a variety of methods, including as described in Kongkanand et al., Single Wall Carbon Nanotube Scaffolds for Photoelectrochemical Solar Cells Capture and Transport of Photogenerated Electrons, Nano Lett., Vol. 7, No. 3, 676-680 (2007), the entire contents of which are hereby incorporated by reference. These images provide a perspective of the overall electrode morphology and the ability to anchor TiO₂ nanoparticles on CFE and SWCNT networks with a good dispersibility. The carbon fibers of the CFE electrode are in micron size (row A) and they serve as the backbone of the electrode in collecting photogenerated electrons and communicating with the external circuit. When TiO₂ particles are dispersed on the CFE, they get dispersed quite uniformly on the carbon microfibers (row B). The higher magnification micrograph confirms the ability of carbon microfibers to support TiO₂ photocatalyst particles and collect photogenerated electrons.

In accordance with another embodiment, SWCNT was deposited on the carbon fiber electrode using an electrophoretic deposition method. This allowed extension of the carbon support network at a nanometer scale. At low magnifications the SWCNT film may be seen covering the voids in the larger carbon microfiber network (row C). The magnified view of the same film shows a close interwoven network of SWCNT bundles. In an embodiment, the CFE/SWCNT was further modified by casting a film of TiO₂ nanoparticles. The figures in row D show the micrograph of the electrode obtained after deposition of TiO₂ nanoparticles on the SWCNT network. In the selected high magnification image, both TiO₂ particle aggregates and the underlying SWCNT network are shown. However, most of the other areas show complete coverage of TiO₂ particles. In an embodiment, the aggregation of TiO₂ particles becomes predominant when the ratio of TiO₂ to SWCNT is increased. If the TiO₂ coverage is kept sufficiently low, in an embodiment, the SWCNT network is expected to interact quite effectively with TiO₂ particles and facilitate charge transport in the composite film.

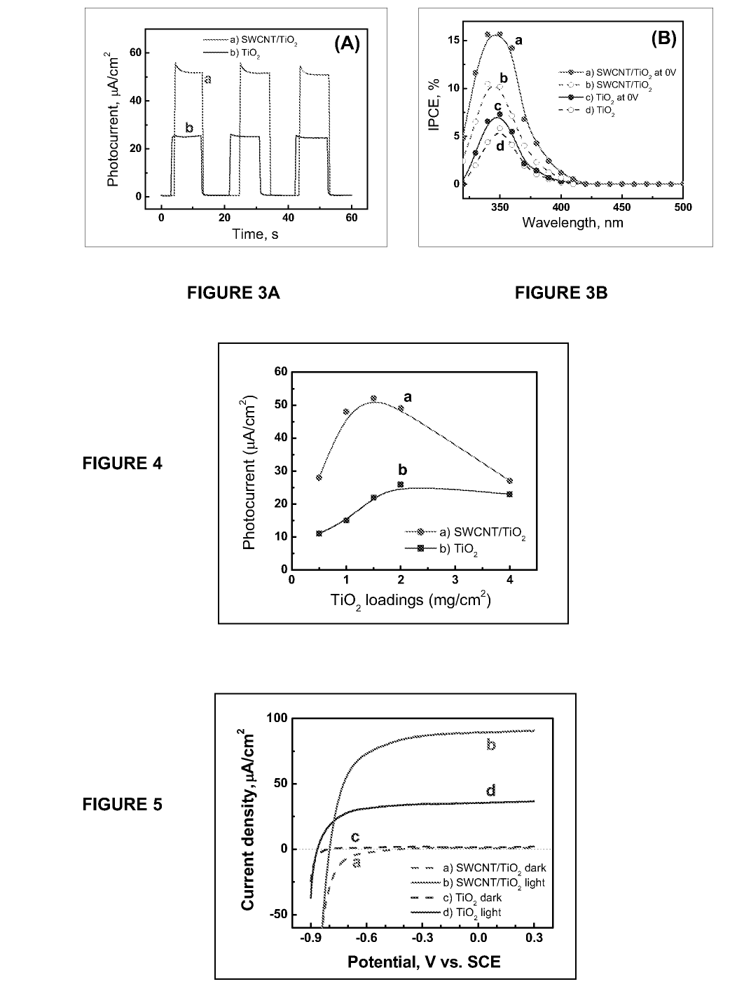

Films of TiO₂ particles undergo charge separation upon excitation with UV-light (E_{g}>3.2 eV). When employed as photoanodes in a photoelectrochemical cell, TiO₂ particulate films cast on electrode surfaces exhibit anodic photocurrent generation. The magnitude of the photocurrent represents the charge collection efficiency of the electrode surface. FIG. 3A shows the short circuit photocurrent generation at CFE/TiO₂ and CFE/SWCNT/TiO₂ electrodes. Both electrodes are prompt in generating photocurrent with a reproducible response to ON-OFF cycles. In an embodiment, the TiO₂ particles deposited on the SWCNT network exhibit an enhanced photocurrent.

In an embodiment, when in contact with photoirradiated TiO₂ nanoparticles, SWCNTs may accept and store electrons. The Fermi level equilibration with photoirradiated TiO₂ particles indicates storage of up to 1 electron per 32 carbon atoms in the SWCNT. The stored electrons are readily discharged on demand upon addition of electron acceptors such as thiazine and oxazine dyes (i.e., acceptors having a lower reduction potential than the SWCNT conduction band) to the SWCNT/TiO₂ suspension. The ability of SWCNT to accept electrons and transfer them to a suitable electron acceptor highlights the mediating role that these nanotubes may play in a charge transfer process.

The stepwise electron transfer from photoirradiated TiO₂ nanoparticles to SWCNT to redox couple has enabled the probing of the electron equilibration process and determination of the apparent Fermi level of the SWCNT/TiO₂ system. SWCNTs undergo charge equilibration with semiconductor particles such as TiO₂ and attain an apparent Fermi level lower (20-30 mV in suspensions and 130 mV in films) than the Fermi level of semiconductor TiO₂. A positive shift in apparent Fermi level indicates the ability of SWCNTs to undergo charge equilibration with photoirradiated TiO₂ particles.

In an embodiment, the effect of electron equilibration between TiO₂ and SWCNT on the photoelectrochemical effect in TiO₂ and SWCNT/TiO₂ films was explored. The films of TiO₂ and SWCNT/TiO₂ were cast on conducting glass electrodes as described previously. These films are photoactive and generate photocurrent under UV-excitation when employed as a photoanode in a photoelectrochemical cell. The primary process responsible for photocurrent generation is the charge separation in TiO₂ particles as they are subjected to bandgap (E_{g}>3.2 eV) excitation.

Under open circuit conditions, the electrons accumulate and equilibrate with the redox couple in the electrolyte. The measured open circuit voltage is the difference between the apparent Fermi level of the semiconductor film and the reduction potential of the redox couple employed. Thus, open-circuit voltage is a direct measure of the apparent Fermi-level of the semiconductor film if one employs the same redox couple. The photovoltage response of optically transparent electrode OTE/TiO₂ and OTE/SWCNT/TiO₂ electrodes shows a rise in photovoltage in two steps: a prompt increase followed by a slow growth as the electrode system equilibrated with the redox couple. Notably, the magnitude of the photovoltage was 130 mV lower for OTE/SWCNT/TiO₂ electrode. The lower photovoltage further supports the notion that the SWCNT/TiO₂ composite has a lower apparent Fermi level than the pristine TiO₂ system. Similar to the charge equilibration effects in suspension, the electrons are transferred from TiO₂ to SWCNT and thus attain a lower equilibrium potential.

It is interesting to note that the photovoltage decay of OTE/SWCNT/TiO₂ is slower than that of OTE/TiO₂ electrode. This observation further indicates the involvement of SWCNT in participating in the electron storage and equilibration process, and thus increasing the survivability of accumulated electrons. Indeed, the ability of SWCNT to accept and transport electrons in the SWCNT/TiO₂ films has a beneficial effect in overall photocurrent generation. In an embodiment, an approximately two-fold increase of incident photon-to-photocurrent generation efficiency was achieved by employing a SWCNT conducting scaffold in TiO₂-nanostructure based photoelectrochemical cells.

In an embodiment, electrode performance was further evaluated by recording the IPCE by monitoring the photocurrent at different incident wavelengths. The photocurrent action spectra of the two electrodes at short circuit and 0 V vs. SCE (standard calomel electrode) are shown in FIG. 3B. Both of these electrodes have a photocurrent onset at 380 nm corresponding to the bandgap of TiO₂. In the absence of SWCNT network, a maximum IPCE of 7.36% (350 nm) at 0 V vs. SCE was observed. The IPCE response shows a significant enhancement with an IPCE of 16% when a SWCNT scaffold supports the TiO₂ particles. Nearly doubling of the photoconversion efficiency is an indication of the improved charge collection efficiency using a SWCNT network.

In accordance with an embodiment, fuel cell experiments carried out with a Pt/SWCNT system shows that both semiconducting and metallic carbon nanotubes contribute to improving the charge transfer and charge collection in both cathodic and anodic compartments. In an embodiment, such charge transport properties of carbon nanotubes may also improve photocurrent generation.

In an embodiment, the role of SWCNT in enhancing the photoelectrochemical performance of TiO₂ film was probed by varying the ratio of SWCNT/TiO₂ in the composite film. The concentration of the SWCNT was kept constant while TiO₂ loading was varied. FIG. 4 compares the photocurrent observed with CFE/TiO₂ and CFE/SWCNT/TiO₂ electrodes at different loading of TiO₂ particles. In the case of the CFE/TiO₂ film, an increase in photocurrent is observed with increased TiO₂ loading (at loadings below 2 mg/cm²) as more excited TiO₂ particles undergo charge separation and participate in the photocurrent generation. At higher TiO₂ loadings, saturation in the photocurrent is observed showing the limitations of light absorption within the TiO₂ film. In the case of CFE/SWCNT/TiO₂, a similar increasing trend is observed at TiO₂ loadings up to 1.5 mg/cm². The photocurrent observed at these TiO₂ loadings is significantly greater than the photocurrent observed without the SWCNT support. This increase in the photoconversion efficiency shows that the SWCNT support architecture plays an important role in improving the charge transport properties within the composite film. At these TiO₂ loadings, SWCNT is capable of dispersing TiO₂ particles quite effectively and facilitating charge collection and transportation toward the collecting electrode surface. At higher loadings, a decrease in the photocurrent is observed as it approaches the value obtained in the absence of SWCNT. At these high TiO₂ loadings, the particles may tend to aggregate and most of these TiO₂ aggregates do not make a direct contact with the SWCNT bundles. The photoelectrochemical behavior at high TiO₂ loadings (4 mg/cm²) thus tends to be similar for both CFE/TiO₂ and CFE/SWCNT/TiO₂. Thus, in an embodiment, beneficial TiO₂ loadings (or other such particles) may be approximately 0.5 to 4 mg/cm².

In order to probe the charge transfer interactions between the excited TiO₂ particles and SWCNT, the current-voltage (I-V) characteristics of the OTE/TiO₂ and OTE/SWCNT/TiO₂ electrodes were analyzed. The films deposited on OTE provided responses similar to those obtained with CFE. In an embodiment, casting of films on OTE allowed annealing of the TiO₂ films at higher temperature (673 K) and better electrochemical performance compared to CFE based electrodes. The I-V characteristics of OTE/TiO₂ and OTE/SWCNT/TiO₂ films in 1 M KOH solution recorded using dark and UV-illumination are shown in FIG. 5.

In accordance with an embodiment, the application of anodic bias facilitates charge separation in TiO₂ particulate films. The anodic bias provides the necessary driving force for transport of electrons to the collecting electrode surface and thus minimizes charge recombination. Both OTE/TiO₂ and OTE/SWCNT/TiO₂ exhibit similar enhanced photocurrent response at positive applied potentials. The OTE/SWCNT/TiO₂ exhibits higher photocurrent than OTE/TiO₂, thus confirming the role of a conducting SWCNT scaffold in improving the overall photoelectrochemical performance. However, the potentials corresponding to zero current (often referred to as flat band potential) are different. The flat band potential as recorded from the zero current potential (FIG. 5) were −0.86 V and −0.79 V versus SCE for TiO₂ and SWCNT/TiO₂ films, respectively. Such a positive shift in the flat band potential is an indication of the electron transfer from TiO₂ to SWCNT as the two systems undergo charge equilibration. Since the conduction band of SWCNT (˜0 V versus NHE (normal hydrogen electrode)) is expected to be lower than that of TiO₂ (−0.5 V versus NHE), charge equilibration is expected between the two systems causing the shift of apparent Fermi level to more positive potentials. In an embodiment, a shift of ˜70 mV in apparent Fermi level of the SWCNT/TiO₂ system is a further indication that the interplay between the two systems in charge equilibration is an important factor in controlling its photoelectrochemical properties.

In an embodiment, since the photogenerated holes reaching the electrode surface participate in the water oxidation reaction, one may evaluate the photoconversion efficiency (q) for the water splitting reaction based on the following expression,

η=power output/incident power=V_{oc}×I_{sc}/I_{inc}

where V_{oc} refers to open circuit voltage, I_{sc} refers to short circuit current and I_{inc} is the incident light intensity (50 mW/cm²). If one assumes the electrolysis efficiency proceeds with 100% water splitting reaction, one may use V_{oc} as 1.23 V (the ideal chemical energy limit at 297 K). Using the current value of 36 and 81 μA/cm² (obtained independently under no bias conditions), an efficiency of 0.09 and 0.20% may be obtained for OTE/TiO₂ and OTE/SWCNT/TiO₂ electrodes (0.06 and 0.12% for CFE/TiO₂ and CFE/SWCNT/TiO₂).

In an embodiment, the influence of SWCNT architectures for facilitating charge transport in mesoscopic semiconductor films has been further probed using a TiO₂/Ru(II)trisbipyridyl complex system. Both transient absorption and emission measurements indicate that the SWCNT network in the film has no noticeable influence on the charge injection process from the excited Ru(II) trisbipyridyl complex into TiO₂ particles. However, it plays an important role in improving the charge separation, as the rate of back electron transfer between the oxidized sensitizer (Ru(III)) and the injected electrons becomes slower in the presence of the SWCNT scaffold. The beneficial aspect of charge collection by SWCNT has been further explored by carrying out photoelectrochemical measurements. In an embodiment, dye-sensitized solar cells constructed using this SWCNT scaffold show an improvement in photocurrent generation. However, this improvement in photocurrent generation may be partially neutralized by a lower photovoltage, as the apparent Fermi level of the TiO₂ and SWCNT composite becomes more positive than that of pristine TiO₂.

In embodiments, semiconductor nanotube assemblies, when assembled on an electrode surface and then modified with dye molecules, offer the possibility to improve the charge collection and transport of charge carriers. While ruthenium is discussed as an exemplary sensitizer, in embodiments, any suitable sensitizer may be utilized, whether a dye, a short bandgap semiconductor, etc. In an embodiment, short bandgap semiconductors such as CdS, PbS, Bi₂S₃, CdSe and InP may serve as sensitizers as they may transfer electrons to large bandgap semiconductors such as TiO₂ or SnO₂ under visible light excitation.

In an exemplary embodiment, both OTE/TiO₂ and OTE/SWCNT/TiO₂ films were immersed in an ethanol solution of Ru(II)(bpy)₂(dcbpy) (henceforth referred to as Ru(II)) for several hours to facilitate the binding of the dye to the TiO₂ surface.

In accordance with an embodiment, films of TiO₂ particles may respond solely to UV light as they undergo charge separation upon bandgap excitation (E_{g}>3.2 eV). When modified with a sensitizer such as Ru(II)(bpy)₂(dcbpy), the TiO₂ particles may directly interact with the excited state of the sensitizer via a charge transfer mechanism (Reactions 1-4):

Ru(II)+hν→Ru(II)* (1)

Ru(II)*→Ru(II)+hν′ (2)

Ru(II)*+TiO₂→Ru(II)+TiO₂(e⁻) (3)

Ru(II)+TiO₂(e⁻)→Ru(II)+TiO₂ (4)

Although a SWCNT does not influence the primary charge injection process in the TiO₂/Ru(II)* system, in an embodiment, it may participate in facilitating charge separation and in promoting electron transport to the electrode surface.

The results suggest that the photoinjected electrons in TiO₂ survive roughly 50% longer when embedded within the SWCNT network. The equilibration of electrons between SWCNT and TiO₂ results in the transfer of a fraction of electrons into SWCNT, thus stabilizing the photogenerated electrons and reducing the rate of exciton recombination.

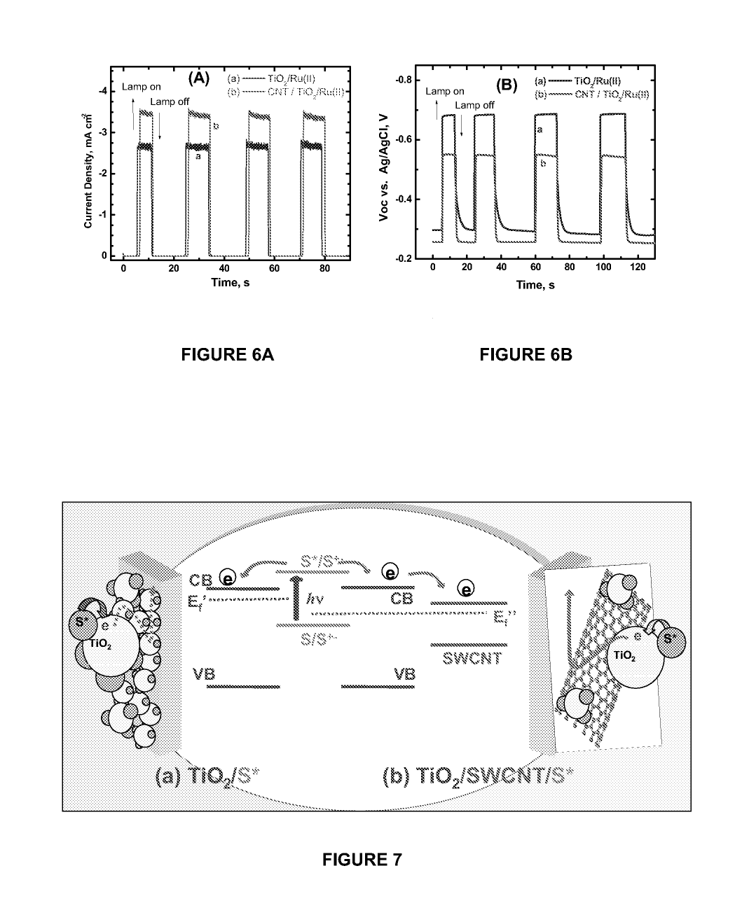

In order to probe the beneficial aspects of a SWCNT network in dye-sensitized solar cells, in accordance with an embodiment, photoelectrochemical cells were constructed using the Ru(II)-modified TiO₂ particulate films as photoanodes. The magnitude of the photocurrent response represents the charge collection efficiency at the electrode surface. FIG. 6A shows the short-circuit photocurrent generation of the OTE/TiO₂/Ru(II) and OTE/SWCNT/TiO₂/Ru(II) electrodes. Both electrodes were prompt in generating photocurrent with a reproducible response to ON-OFF cycles. It is interesting to note that the films containing a SWCNT network exhibited a roughly 30% higher photocurrent. This increase is greater than the small (2.3%) difference in absorbance between OTE/TiO₂/Ru(II) and OTE/SWCNT/TiO₂/Ru(II) films. On the other hand, the photovoltage (FIG. 6B) recorded during ON-OFF cycles shows a decreased open-circuit voltage when SWCNT was present in the film.

The two opposing trends seen in the short-circuit current and open-circuit voltage (FIGS. 6A and 6B) may be explained on the basis of the electron capture properties of SWCNT. As the photoinjected electrons are transferred to TiO₂ from excited Ru(II)*, they undergo charge equilibration with SWCNT. This charge equilibration is associated with the shifting of the apparent Fermi level to more positive potentials. A positive shift of tens to hundreds of millivolts in the apparent Fermi level has been noted from the redox equilibration experiments. This shift causes the open-circuit voltage of the photoelectrochemical cell, which is dependent on the difference in Fermi levels between the photoanode and the redox couple, to be lower than that obtained in the absence of SWCNT. The electrons transferred into the SWCNT network may be quickly transported to the collecting electrode surface, minimizing the possibility of charge recombination at grain boundaries. The incorporation of a SWCNT network in the TiO₂ film thus helps to transport electrons through its conductive scaffold and to generate higher photocurrent, at the expense of the open-circuit potential (see FIG. 7).

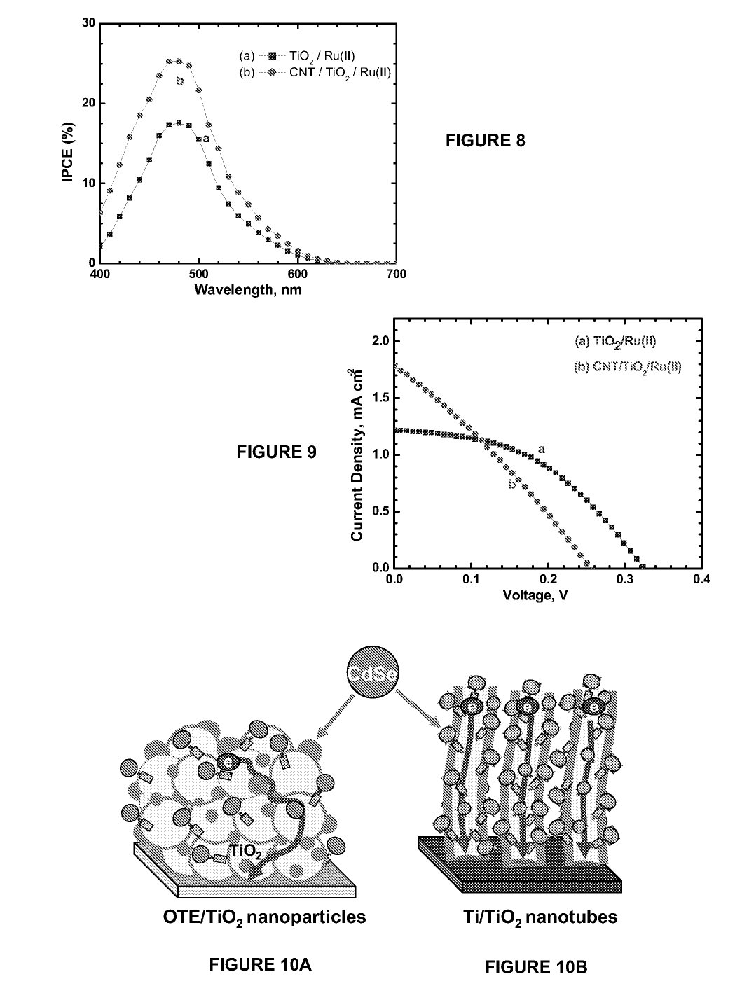

In an embodiment, the electrode performance was further evaluated by recording the IPCE at different incident wavelengths of light. The photocurrent action spectra of the two electrodes under unbiased conditions are shown in FIG. 8. Both of these electrodes exhibit an IPCE maximum corresponding to the absorption maximum of the Ru(II) complex. In an embodiment, the IPCE response at all wavelengths is enhanced by a factor of ˜1.4 as a result of introducing a SWCNT scaffold in the TiO₂ film. Suppressing the back electron transfer and improving the electron transport within the nanostructured TiO₂ film are regarded as the two most important factors controlling the overall IPCE of the cell. Enhancement in the photoconversion efficiency in the present embodiments suggests that charge collection and transport in these films are improved by the SWCNT network.

In an embodiment, the power characteristics were also evaluated by varying the load resistance (FIG. 9). A 45% increase in short circuit current seen with the SWCNT nanostructure is consistent with the IPCE and photocurrent measurements described earlier. However, the open-circuit voltage is decreased by about 60 mV as a result of charge equilibration between TiO₂ and SWCNT. A shift in open-circuit potential was also noted in UV-irradiated SWCNT/TiO₂ films. In an embodiment, since the conduction band of SWCNT (˜0 V vs. NHE) is expected to be more positive than that of TiO₂ (−0.5 V vs. NHE), charge equilibration is expected between the two systems causing the shift of apparent Fermi level to more positive potentials. Spectroscopic and photoelectrochemical measurements have also confirmed the ability of SWCNT to accept electrons and undergo charge equilibration. The power conversion efficiency for the DSSC's employing OTE/TiO₂/Ru(II) and OTE/SWCNT/TiO₂/Ru(II) electrodes were 0.18% and 0.13%, respectively. The similarity between these two values suggests that improvement in photocurrent may be at least partially nullified by the decrease in photovoltage. As a result of these opposing factors, a small decrease in the fill factor and net power conversion efficiency may be seen.

In an embodiment, quantum dots, such as CdSe quantum dots, may be assembled on TiO₂ films composed of nanoparticle and/or nanotube morphologies to enhance their function. In an embodiment, the quantum dots may be coupled to the nanoparticles/nanotubes using a bifunctional linker molecule (see FIGS. 10A and 10B). The hollow nature of the nanotubes makes both inner and outer surface areas accessible for modification with sensitizing dyes and/or semiconductor quantum dots. Further information regarding quantum dot solar cells and tuning of the photoresponse through size and shape control of the quantum dots may be found in Kongkanand, et al., Quantum Dot Solar Cells—Tuning Photoresponse Through Size and Shape Control of CdSe—TiO₂ Architecture, J. Am. Chem. Soc., Published on Web, Mar. 1, 2008, the entire contents of which are hereby incorporated by reference.

In accordance with an embodiment, upon bandgap excitation, CdSe quantum dots may inject electrons into TiO₂ nanoparticles/nanotubes, thus enabling the generation of photocurrent in an associated photoelectrochemical solar cell. Embodiments of the invention thus provide: (i) an ability to tune the photoelectrochemical response and/or photoconversion efficiency via size control of quantum dots, and (ii) improvement in photoconversion efficiency by facilitating charge transport through the nanotube architecture.

In accordance with an embodiment, the IPCE obtained with 3 nm diameter CdSe nanoparticles was 35% for particulate TiO₂ and 45% for tubular TiO₂ morphology. The IPCE observed at the excitonic band increases with decreasing particle size, as the shift in conduction band to more negative potentials increases the driving force and favors fast electron injection. The power conversion efficiency ≦1% obtained with CdSe—TiO₂ nanotube films highlights the usefulness of tubular morphology in facilitating charge transport in nanostructure based solar cells.

While CdSe quantum dots are discussed throughout this application as exemplary quantum dots, other quantum dots may be utilized, such as PbSe, InAs, etc.

In an embodiment, various linker molecules may be used to link the quantum dots to the nanoparticles and/or nanotubes. In an embodiment, bifunctional linker molecules, such as MPA (HOOC—CH₂—CH₂—SH), which have both carboxylate and thiol functional groups, facilitate binding between CdSe quantum dots and TiO₂ surfaces. The CdSe quantum dots bound to the TiO₂ surface inherit native quantization properties. The shift in onset absorption with decreasing particle size is similar in both OTE/TiO₂(NP)/CdSe and Ti/TiO₂(NT)/CdSe electrodes. Relatively high absorption of the visible light (absorbance ˜0.7) by these electrodes ensures absorbance of more than 80% of the incident light at wavelengths below the onset.

In accordance with an embodiment, success in achieving relatively high coverage of CdSe quantum dots on these TiO₂ films highlights the ability of small size CdSe quantum dots to penetrate the porous network of a TiO₂ film and provide a uniform coverage throughout the film.

The open-circuit potential is independent of CdSe particle size indicating that electrons injected from excited CdSe into TiO₂ quickly relax to the lowest conduction band energy. Hence the conduction band level of TiO₂ and the redox potential of the sulfide electrolyte alone dictate an open-circuit voltage of ˜600 mV.

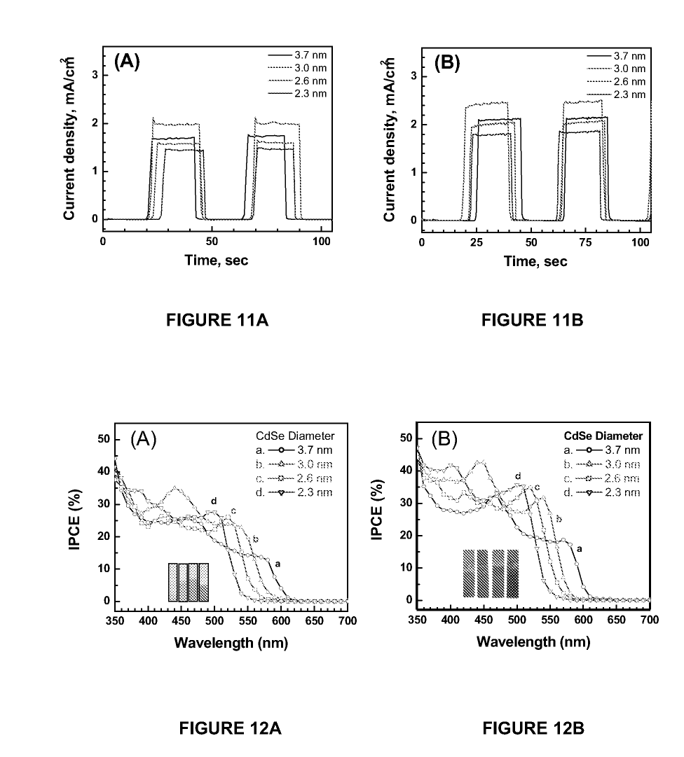

The photocurrent response, however, varies with particle size (see FIGS. 11A and 11B). Of those tested, the maximum photocurrent is seen with 3.0 nm diameter CdSe particles. Two opposing effects account for the difference in photocurrent generation at OTE/TiO₂/CdSe electrodes. Decreasing particle size of CdSe increases photocurrent as the shift in conduction band to more negative potentials increases the driving force for charge injection. On the other hand, decreasing the CdSe particle size lowers photocurrent due to an inherently smaller response in the visible region.

In an embodiment, the photoelectrochemical response may be tuned through size quantization. The photoelectrochemical response of both OTE/TiO₂/CdSe films to monochromatic light irradiation was analyzed in terms of IPCE. The IPCE was determined from short circuit photocurrents (J_{sc}) monitored at different excitation wavelengths (λ) using the expression:

$$IPCE \% = \frac{1240 \times {J}_{short circuit} ( A / {cm}^{2} )}{λ ( nm ) \times {I}_{incident} ( W / {cm}^{2} )} \times 100 \%$$

where I_{incident} is the energy of the monochromatic light incident on the electrode. The IPCE action spectra for OTE/TiO₂(NP)/CdSe and Ti/TiO₂(NT)/CdSe electrodes are presented in FIGS. 12A and 12B. The photocurrent action spectra obtained with 3.7, 3.0, 2.6, and 2.3 nm CdSe particles show similar trends for both films. The current peaks may be observed at 580, 540, 520 and 505 nm. Thus, in an embodiment, the photocurrent generation at OTE/TiO₂(NP)/CdSe and Ti/TiO₂(NT)/CdSe electrodes originates from the individual CdSe quantum dots and their size quantization property is responsible for tuning the performance of quantum dot solar cells. In particular, the ability to tune the photoresponse by varying the size of CdSe particles affords the ability to tune the performance of quantum dot solar cells.

Comparison of IPCE at the excitonic peaks shows an interesting dependence on the particle size. The IPCE values measured at 580 nm (d=3.7 nm), 540 nm (d=3.0 nm), 520 nm (d=2.6 nm) and 505 nm (d=2.3 nm) were 14, 24, 26 and 28% for OTE/TiO₂(NP)/CdSe and 19, 32, 35 and 36% for Ti/TiO₂(NT)/CdSe respectively. It should be noted that the absorbance at the excitonic band was matched to 0.7±0.05. The difference in absorption (≦5%) is smaller than the variation in the IPCE for these four electrodes. Hence, the strong dependence of IPCE on particle size is not due to the relatively small difference in absorption between the two electrodes. The improved IPCE with smaller size quantum dots may arise from the improved rate of electron transfer. The smaller size particles, being more energetic in their excited state, are capable of injecting electrons into TiO₂ at a faster rate.

It is also interesting to note that the maximum IPCE obtained with CdSe quantum dots linked to TiO₂ particles and tubes are different. The maximum IPCE values in the visible region range from 25% to 35% for OTE/TiO₂(NP)/CdSe electrodes while they vary from 35% to 45% for OTE/Ti/TiO₂(NT)/CdSe electrodes. These IPCE values are relatively higher than those reported in the literature for the sensitization of TiO₂ films (IPCE 25%) and ZnO nanorods (IPCE=18%) with CdSe quantum dots. Note that the comparison made here is based on IPCE or external quantum efficiency values and not based on absorbed light harvesting efficiencies or APCE values.

Although in embodiments, nanotube TiO₂ films generally absorb more light than nanoparticle TiO₂ films, this difference accounts for a no more than 5% increase in overall photons absorbed. Comparing this with a ˜10% improvement in IPCE of the nanotube film over the nanoparticle film, as represented in an exemplary embodiment, demonstrates an advantage of a nanotube architecture for facilitating electron transport in nanostructure based semiconductor films. The electrons in the particulate TiO₂ films are more susceptible to loss at grain boundaries than those in nanotube TiO₂ films. In addition, one also needs to take into consideration the role of crystal structure and surface defects between TiO₂ tubes and particles during their interaction with CdSe quantum dots.

The open-circuit voltage recorded after stopping the illumination shows slower decrease for Ti/TiO₂(NT)/CdSe than for Ti/TiO₂(NP)/CdSe electrodes. Under open-circuit conditions, electrons may accumulate within the nanostructure semiconductor films following visible irradiation and shift the apparent Fermi level to negative potentials. Once the illumination is stopped, the accumulated electrons may be slowly discharged as they are scavenged by the redox species in the electrolyte. The slower decay observed with tubular morphology is a further indication that the electrons injected from excited CdSe may survive longer and hence may facilitate electron transport without undergoing losses at the grain boundaries. The results discussed here demonstrate an advantage of assembling semiconductor particles or light harvesting assemblies on nanotube architecture for improving the photocurrent generation efficiency of solar cells.

In an embodiment, short bandgap semiconductors (e.g., CdS, PbS, Bi₂S₃, CdSe, InP) may be used as sensitizers to extend the photoresponse of TiO₂ into the visible region. CdSe quantum dots are capable of injecting electrons into the conduction band of TiO₂ in a manner analogous to sensitizing dyes. The lower lying conduction band of TiO₂ (−0.5 V vs. NHE) compared to quantized CdSe (≦−1.0 V vs. NHE) is expected to minimize the charge recombination and rectify the transport of charge carriers.

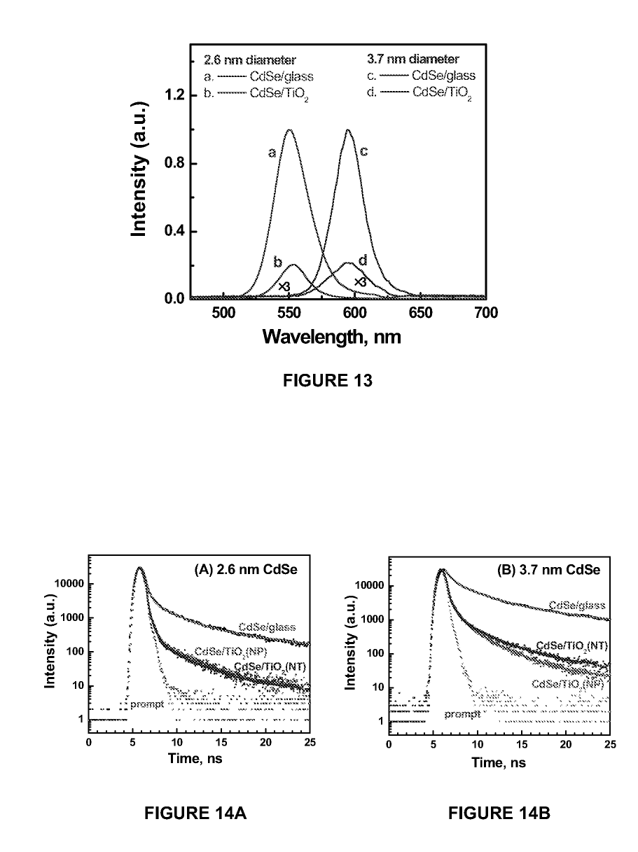

The CdSe particles exhibit a band edge emission peak which also shifts to the blue region with decreasing particle size. FIG. 13 (a,c) shows the emission spectra of 2.6 and 3.7 nm CdSe quantum dots deposited on glass slides. These quantum dots exhibit characteristic emission peaks at 550 nm and 600 nm respectively. When CdSe is anchored onto a TiO₂ film (b,d) a significant quenching of the emission is seen, thus confirming the excited state interaction between the two semiconductor particles. This quenching behavior represents the deactivation of the excited CdSe via electron transfer to TiO₂ particles. The processes that follow the bandgap excitation of CdSe are presented in Equations 1-3:

CdSe+hν→CdSe(e+h)→CdSe+hν (1)

CdSe(e)+TiO₂→CdSe+TiO₂(e) (2)

CdSe(h)+Red→CdSe+Ox (3)

While the electrons injected into TiO₂ are collected to generate photocurrent, in an embodiment, a redox couple may be employed to scavenge the holes (Equation 3). Failure to scavenge holes may lead to surface oxidation, especially during extended periods of irradiation. In a typical photoelectrochemical cell, such oxidation may be minimized by using a sulfide electrolyte.

The excited CdSe deactivation may be further analyzed by monitoring the emission decay. FIGS. 14A and 14B show the emission decay recorded with 2.6 and 3.7 nm CdSe quantum dots. The emission decay was multiexponential as the distribution in the recombination rate constants influenced the decay kinetics. Triexponential decay kinetics were found to be satisfactory in the determination of emission lifetimes. These values were then used to estimate the average lifetime of CdSe emission decay using the following expression:

$$〈 τ 〉 = \frac{{a}_{1} {τ}_{1}^{2} + {a}_{2} {τ}_{2}^{2} + {a}_{3} {τ}_{3}^{2}}{{a}_{1} {τ}_{1} + {a}_{2} {τ}_{2} + {a}_{3} {τ}_{3}}$$

When deposited on a glass slide, 2.6 and 3.7 nm CdSe particles exhibited emission decay with average lifetimes of 4.1 and 7.9 ns respectively. When anchored on TiO₂ particles the average time decreased to 0.4 and 1.3 ns for 2.6 and 3.7 nm diameter CdSe quantum dots respectively. Similar decrease in the CdSe emission lifetime was also seen in the case of TiO₂ nanotubes.

If one assumes the observed decrease in lifetime to the charge transfer to TiO₂ one can estimate the charge transfer rate constant by the following expression:

$${k}_{et} = \frac{1}{{τ}_{( CdSe + {TiO}_{2} )}} - \frac{1}{{τ}_{( CdSe )}}$$

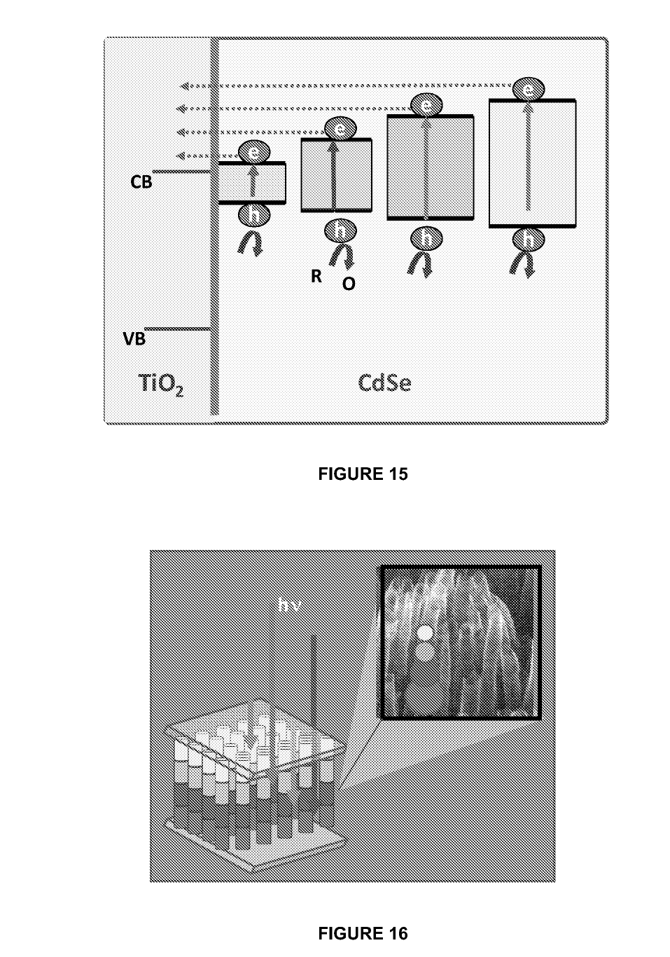

Using observed lifetime values, electron transfer rate constant of 2.5×10⁹ s⁻¹ and 0.63×10⁹ s⁻¹ for 2.6 and 3.7 nm diameter CdSe quantum dots on particulate TiO₂ films may be obtained. Similar rate constants were also observed for TiO₂ nanotubes. Similarity between the rate constant values observed for TiO₂ particles and TiO₂ nanotubes indicates that the charge injection dynamics are dictated mostly by the energetics of quantized CdSe particles and not the morphology of the acceptor TiO₂. The conduction band of TiO₂ is at −0.5 V versus NHE. Larger CdSe particles with the bulk properties have band energy close to the reported value of −0.8 V vs. NHE. The difference between the two conduction band energy levels serves as a driving force for the interparticle electron transfer (see FIG. 15). Since the shift in the conduction band energy is significantly greater than the shift in valence band energy for quantized particles, the conduction band of CdSe quantum dots may be expected to become more negative (on NHE scale) with decreasing particle size. Thus, an increase of a factor of two in the charge injection rate constant may be seen when 2.6 nm CdSe instead of 3.7 nm quantum dots are used.

In an embodiment, further optimization of cell configuration and improvements in the light absorption properties of the electrodes may be utilized to further improve the performance of quantum dot photovoltaic cells (such as solar cells). In an embodiment, one such approach is the construction of a rainbow solar cell which employs an ordered assembly of nanoparticle quantum dots, such as CdSe, of different diameter. An example of TiO₂ nanotubes decorated with different sized CdSe nanoparticles is shown in FIG. 16. As white light enters the cell, smaller size nanoparticles (larger bandgap) absorb the portion of the light with smaller wavelengths (blue region). Light with longer wavelengths (red region) which is transmitted through the initial layer is absorbed by subsequent layers, and so on. By creating an orderly gradient of quantum dots of different size, the effective capture of incident light may be enhanced.

In an embodiment, smaller size particles exhibit higher photoconversion efficiency but absorb less light than larger size particles. In an embodiment, if the quantized particles are anchored on a nanotube array, incident light may be captured while collecting and transmitting electrons through the nanotube network. It is true that the excess energy of electrons of small size particles may be lost once transferred to a supporting manifold; however, such a rainbow cell configuration allows one to couple the faster electron injection rate of small size particles and greater absorption range of large particles effectively.

Thus, in an embodiment there is provided a nanostructure comprising a nanomaterial comprised of nanoparticles and/or nanotubes, the nanomaterial coupled at one or more locations to a substrate, and a plurality of quantum dots coupled to the nanomaterial, at least two of the plurality of quantum dots being differently sized. In an embodiment, differently sized quantum dots may be randomly distributed on the nanomaterial, or may be ordered, or a combination of random and ordered arrangements may be used. In an embodiment, ordered quantum dots may be arranged with a short wavelength quantum dot located closer to a light source (such as the sun) than a longer wavelength quantum dot. In such an embodiment, the arrangement of the quantum dots may be done in accordance with the intended direction of the light source, although may contact the quantum dots from other directions as well. In an embodiment, ordered quantum dots may be arranged to form a size gradient (whether partial or completely uniform) with shorter wavelength quantum dots located a greater distance away from the substrate and longer wavelength quantum dots located closer to the substrate.

In an embodiment there is provided a photovoltaic cell (such as a solar cell) comprising a collecting electrode substrate, a nanomaterial scaffold comprising nanoparticles and/or nanotubes, the nanomaterial scaffold coupled at one or more locations to the substrate, and a plurality of quantum dots and/or nanoparticles coupled to the nanomaterial scaffold. In an embodiment, the collecting electrode substrate may be coupled to or have one or more integrated conducting elements to move the charge/current to a location for use and/or storage. Other components of a photovoltaic cell as known in the art or later developed, such as anti-reflection coatings, concentrating or focusing lenses or other such systems, etc. may be incorporated with embodiments as provided above.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

What is claimed is:

1. A nanostructured material, comprising:
a single wall carbon nanotube having a first and second end and an outer and inner surface, the first end of the single wall carbon nanotube coupled to a substrate; and
a plurality of nanoparticles coupled to the single wall carbon nanotube.

2. The nanostructured material of claim 1, wherein the nanoparticles comprise at least one of TiO₂ and SnO₂.

3. The nanostructured material of claim 1, wherein at least one of the plurality of nanoparticles is coupled to the outer surface of the single wall carbon nanotube.

4. The nanostructured material of claim 1, wherein at least one of the plurality of nanoparticles is coupled to the inner surface of the single wall carbon nanotube.

5. The nanostructured material of claim 1, wherein the nanoparticles are loaded on the single wall carbon nanotube at approximately 0.5 to 4 mg/cm².

6. The nanostructured material of claim 1, wherein the substrate is configured to accept electrons traveling through the single wall carbon nanotube to create a current.

7. The nanostructured material of claim 1, further comprising one or more quantum dots coupled to the single wall carbon nanotube and/or coupled to one or more of the plurality of nanoparticles.

8. The nanostructured material of claim 7, wherein the one or more quantum dots are coupled to the single wall carbon nanotube and/or coupled to one or more of the plurality of nanoparticles via a linker molecule.

9. The nanostructured material of claim 7, wherein the one or more quantum dots comprise at least one of CdSe, CdTe, PbSe, and InAs.

10. The nanostructured material of claim 7, wherein at least one of the one or more quantum dots is coupled to the outer surface of the single wall carbon nanotube.

11. The nanostructured material of claim 7, wherein at least one of the one or more quantum dots is coupled to the inner surface of the single wall carbon nanotube.

12. The nanostructured material of claim 1, further comprising one or more sensitizers coupled to the single wall carbon nanotube and/or coupled to one or more of the plurality of nanoparticles.

13. The nanostructured material of claim 12, wherein the one or more sensitizers comprise a dye.

14. The nanostructured material of claim 13, wherein the dye is ruthenium.

15. The nanostructured material of claim 12, wherein the one or more sensitizers comprise a short bandgap semiconductor.

16. The nanostructured material of claim 15, wherein the short bandgap semiconductor is at least one of CdS, PbS, Bi₂S₃, CdSe and InP.

17. A nanostructure comprising:
a nanomaterial comprised of nanoparticles and/or nanotubes, the nanomaterial coupled at one or more locations to a substrate; and
a plurality of quantum dots coupled to the nanomaterial, at least two of the plurality of quantum dots being differently sized.

18. The nanostructure of claim 17, wherein the differently sized quantum dots are randomly distributed on the nanomaterial.

19. The nanostructure of claim 17, wherein the differently sized quantum dots are ordered on the nanomaterial.

20. The nanostructure of claim 19, wherein the ordered quantum dots are arranged with a short wavelength quantum dot located closer to a light source than a longer wavelength quantum dot.

21. The nanostructure of claim 19, wherein the ordered quantum dots are arranged to form a size gradient with shorter wavelength quantum dots located a greater distance away from the substrate and longer wavelength quantum dots located closer to the substrate.

22. The nanostructure of claim 17, wherein the one or more quantum dots are coupled to the nanomaterial via a linker molecule.

23. A photovoltaic cell, comprising:
a collecting electrode substrate;
a nanomaterial scaffold comprising nanoparticles and/or nanotubes, the nanomaterial scaffold coupled at one or more locations to the substrate; and
a plurality of quantum dots and/or nanoparticles coupled to the nanomaterial scaffold.
